(19) United States
(12) Patent Application Publication
(10) Pub. No.: US 2010/0258175 A1
(43) Pub. Date: Oct. 14, 2010

(54) PANCHROMATIC PHOTOSENSITIZERS AND DYE-SENSITIZED SOLAR CELL USING THE SAME

(76) Inventors: Yun Chi, Hsinchu (TW); Kellen Chen, Hsinchu (TW); Yi-Huan Hong, Hsinchu (TW); Pi-Tai Chou, Taipei (TW); Bo-So Chen, Taipei (TW); Hui-Chu Hsu, Hsinchu (TW)

Correspondence Address: Muncy, Geissler, Olds & Lowe, PLLC, 4000 Legato Road, Suite 310, FAIRFAX, VA, 22033, US

(21) Appl. No.: 12/495,044

(22) Filed: Jun. 30, 2009

(30) Foreign Application Priority Data
Apr. 10, 2009 (TW) 98111934

(51) Int. Cl. H01L 31/00; C07F 15/00

(52) U.S. Cl. 136/256; 546/10; 546/2

(57) ABSTRACT

Panchromatic photosensitizers having a Formula of ML₁L₂X were synthesized, wherein M comprises ruthenium atom; X is a monodentate anion; L₁ is heterocyclic bidentate ligand having one of formulae listed below:

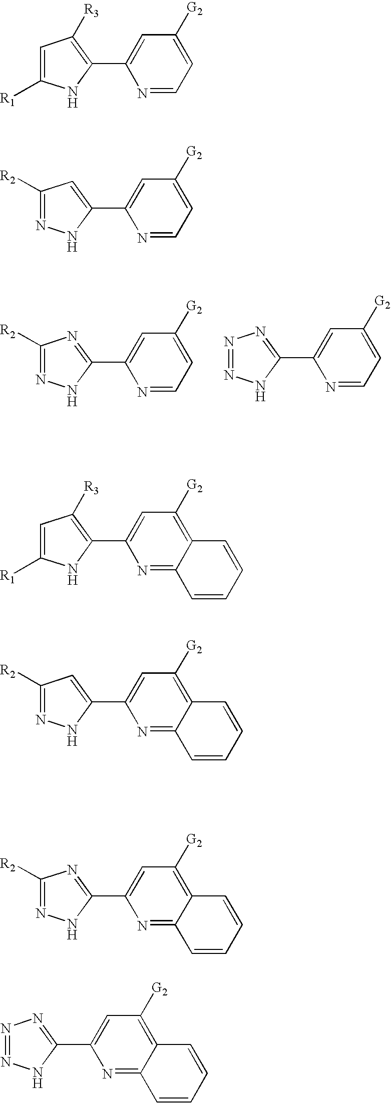

wherein G₂ has one of formulae listed below:

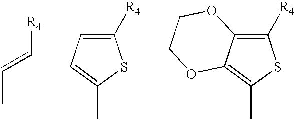

and L₂ is a tridentate ligand having a formula listed below:

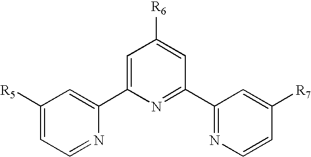

The substituents R₁, R₂, R₃, R₄, R₅, R₆, R₇ of L₁ and L₂ are the same or different, and represent alkyl, alkoxy, alkylthio, alkylamino, halogenated alkyl, phenyl or substituted phenyl group, carboxylic acid or counter anion thereof, sulfonic acid or counter anion thereof, phosphoric acid or counter anion thereof, amino-group, halogens, or hydrogen. The above-mentioned photosensitizers are suitable to use as sensitizers for fabrication of high efficiency dye-sensitized solar cell.

### BACKGROUND OF THE INVENTION

1. Field of the Invention

The present invention is related to panchromatic photosensitizers and dye-sensitized solar cell using the same, and more particularly to panchromatic photosensitizers and dye-sensitized solar cell using the same with better photoelectric conversion efficiency.

2. Description of the Prior Art

Petrochemical fuel contains nonrenewable energy, which will possibly run out very soon. In addition, burning petrochemical fuel results in excessive CO₂ exhausts which not only pollute the air, but also become one of the primary causes of global warming. Therefore, searching for alternative energy supplies to reduce reliance on petrochemical fuels is a subject of great urgency. During the development of green energy, it is found that solar energy is the cleanest, most abundant and requires neither mining nor refinement. Solar energy, therefore, becomes the most notable field among the current development and search for new energy.

The manufacture of a dye-sensitized solar cell (DSSC) is simple and the manufacturing cost is also lower than that of a silicon-based solar cell of prior arts. Therefore, DSSC has been regarded as one of the most promising solar cell technologies following silicon-based solar cells. Because the intrinsic property of photosensitizers directly affects the photoelectric conversion efficiency of a DSSC, the photosensitizers then becomes one of key focus while conducting research on DSSCs.

A N3 dye is a photosensitizer commonly used at present, which comprises the structure shown in Formula (I). However, the absorption spectrum of N3 dye is not well matched to the solar spectrum, which makes N3 dye to respond sluggishly to solar irradiations with wavelengths greater than 600 nm, and cannot be used in this region efficiently.

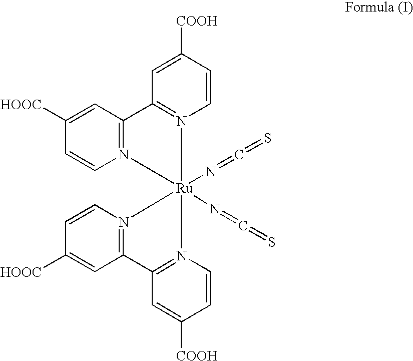

Another photosensitizer of prior art is the black dye, which comprises the structure shown in Formula (II). Although black dye somewhat overcomes the drawback of N3 dye, and exhibits spectrum response up to the region of 920 nm, the process involving its synthesis is complicated, the absorption extinction coefficient in the visible region is inferior to those of the typical organic sensitizers, and not to mention of the poor synthetic yield.

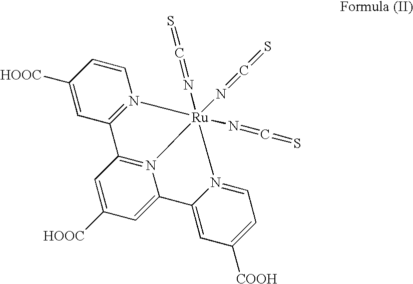

To sum up the foregoing descriptions, the photoelectric conversion efficiency of a DSSC directly depends on the property of a photosensitizer; therefore, developing photosensitizers with decent photoelectric conversion efficiency is an important goal to be achieved.

### SUMMARY OF THE INVENTION

The present invention is directed to providing a panchromatic photosensitizers and dye-sensitized solar cell using the same with better spectrum response and photoelectric conversion efficiency.

According to an embodiment, A photosensitizer comprises a chemical formula represented by Formula (a):

ML₁L₂X Formula (a)

wherein M comprises ruthenium atom; X represents a monodentate anion; L₁ represents heterocyclic bidentate ligand comprising a structural formula represented by Formula (b) or Formula (c) listed below:

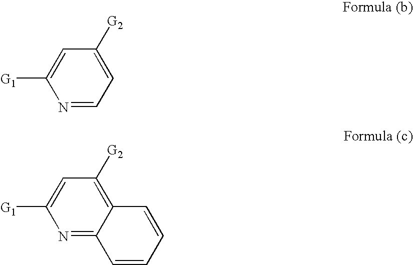

wherein G₁ comprises a structural formula represented by Formula (d), Formula (e) Formula (f) or Formula (g) listed below:

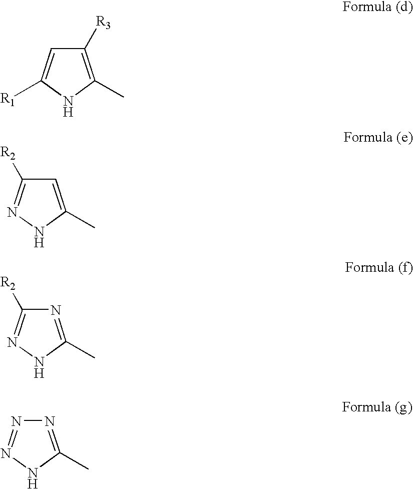

G₂ comprises a structural formula represented by Formula (h), Formula (i) or Formula (j) listed below:

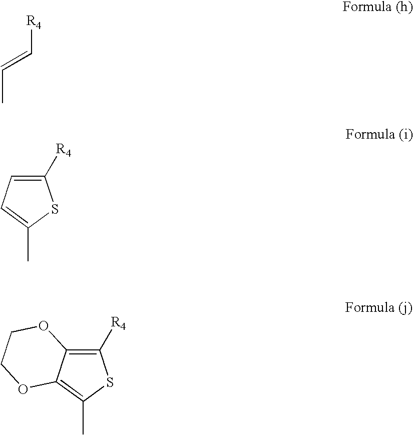

and L₂ represents a tridentate ligand comprising a structural Formula (k) listed below:

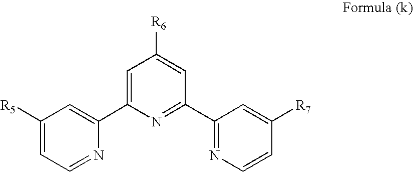

wherein the substituents R₁, R₂, R₃, R₄, R₅, R₆ and R₇ of L₁ and L₂ are the same or different, and represent alkyl, alkoxy, alkylthio, alkylamino, halogenated alkyl, phenyl or substituted phenyl group, carboxylic acid or counter anion thereof, sulfonic acid or counter anion thereof, phosphoric acid or counter anion thereof, amino-group, halogens, or hydrogen.

According to another embodiment, a DSSC comprises a first electrode, a second electrode and an electrolyte. The first electrode comprises a transparent conductive substrate and a porous membrane, wherein the porous membrane, disposed on a surface of the transparent conductive substrate, comprises a semiconductor material and is loaded with the aforementioned photosensitizers. The electrolyte is disposed between the porous membrane and the second electrode.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same and become better understood by reference to the following detailed descriptions, when taken in conjunction with the accompanying drawings, wherein:

FIG. 1 is a curve diagram illustrating absorption spectrum of a black dye of prior art and photosensitizers according to an embodiment of the present invention, respectively; and

FIG. 2 is a diagram schematically illustrating the structure of a dye-sensitized solar cell according to an embodiment of the present invention.

### DESCRIPTION OF THE PREFERRED EMBODIMENT

An embodiment of photosensitizers have a chemical formula of Formula (a):

ML₁L₂X Formula (a)

wherein M comprises ruthenium atom; X represents a monodentate anion; L₁ represents a heterocyclic bidentate ligand; and L₂ represents a tridentate ligand. In one embodiment, the X comprises halide, pseudohalide, carboxylate, carbanion, sulfate, phosphate, thiocyanate or other organic anion. L₁ comprises a structural formula represented by Formula (b) or Formula (c) listed below:

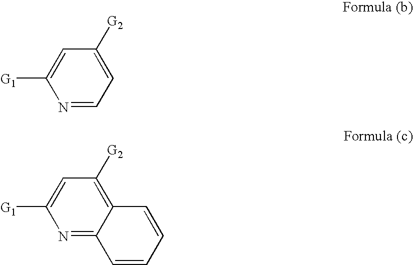

wherein G₁ comprises a structural formula represented by Formula (d), Formula (e), Formula (f) or Formula (g) listed below:

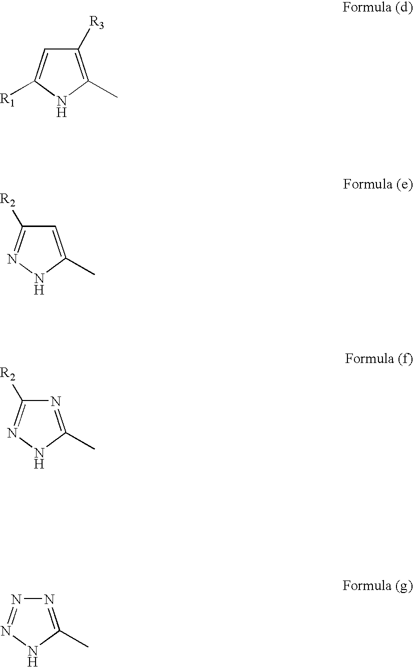

G₂ comprises a structural formula represented by Formula (h), Formula (i) or Formula (j) listed below:

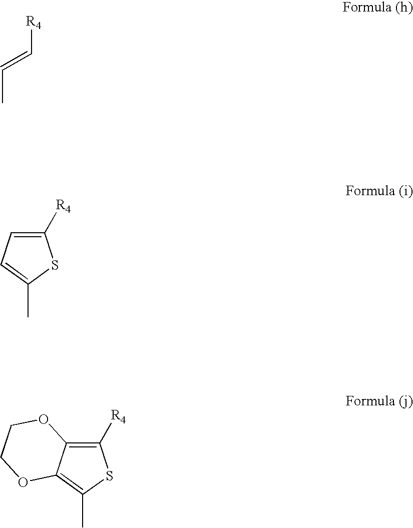

and L₂ comprises a structural formula represented by Formula (k) listed below:

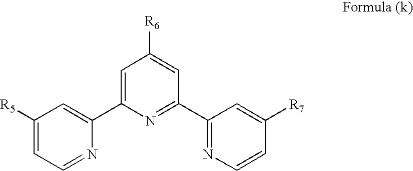

wherein the substituents R₁, R₂, R₃, R₄, R₅, R₆ and R₇ of L₁ and L₂ are the same or different, and represent alkyl, alkoxy, alkylthio, alkylamino, halogenated alkyl, phenyl or substituted phenyl group, carboxylic acid or counter anion thereof, sulfonic acid or counter anion thereof, phosphoric acid or counter anion thereof, amino-group, halogens, or hydrogen.

In one embodiment, the substituents R₁ and R₃ of L₁ are the same or different, and represent hydrogen, isobutyl or CF₃. The substituent R₂ of L₁ comprises hydrogen, isobutyl, CF₃, or a structural formula represented by Formula (l) or Formula (m) listed below:

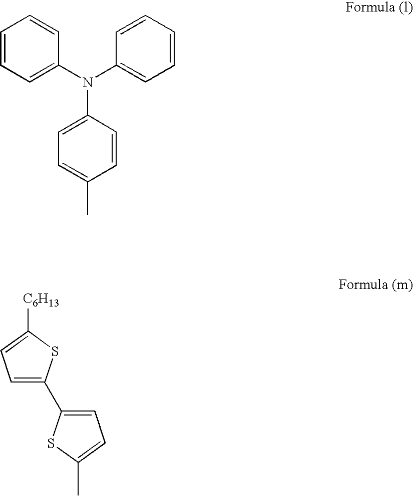

In one embodiment, the substituent R₄ of L₁ comprises an aromatic ring or a functional group of substituted conjugated double bond thereof. Taking Formula (h) for example, G₂ comprises the following structure:

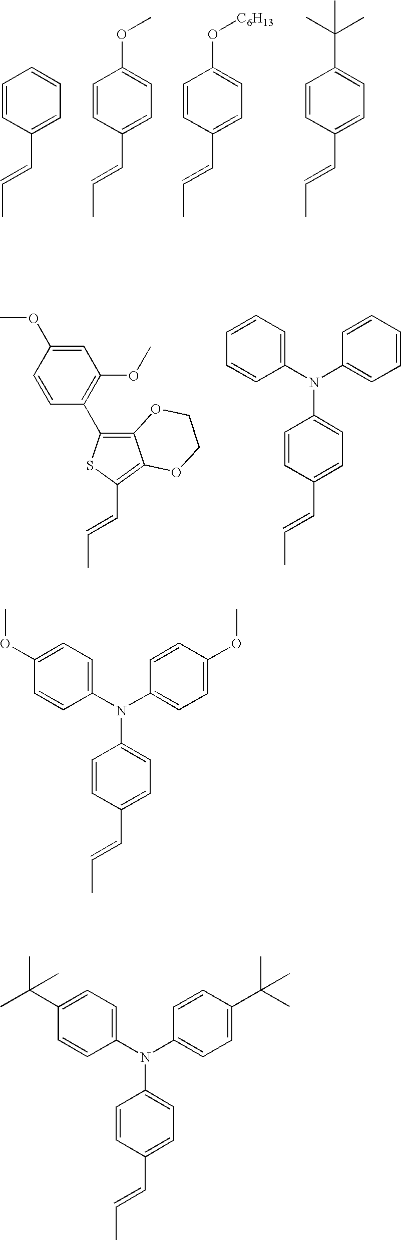

In one embodiment, the substituents R₅, R₆ and R₇ of L₂ are the same or different, and represent hydrogen, carboxylic acid or counter anion thereof, sulfonic acid or counter anion thereof, phosphoric acid or counter anion thereof. For example, L₂ comprises the following structure:

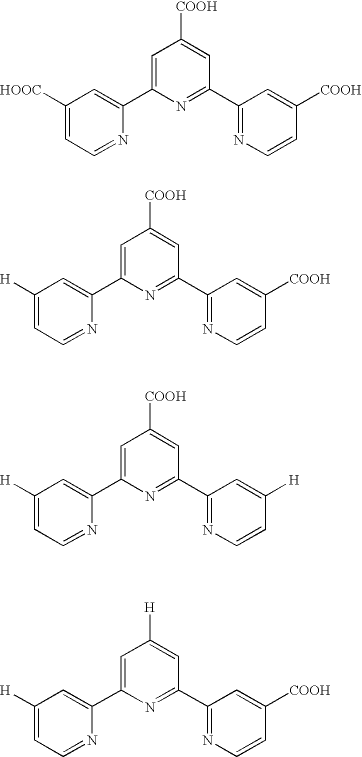

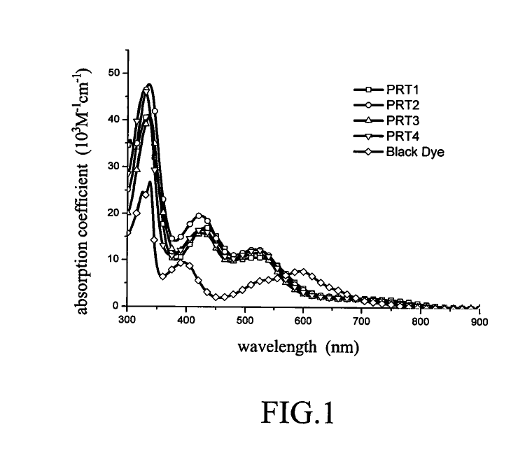

Referring to FIG. 1, which illustrates an absorption spectrum of photosensitizers of the present invention with the structure of Formula (n) and of a black dye, respectively,

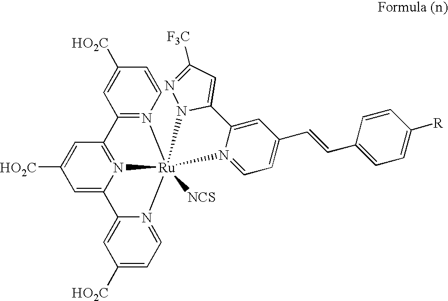

wherein R in photosensitizer PRT1 is hydrogen; R in photosensitizer PRT2 is OCH₃; R in photosensitizer PRT3 is OC₈H₁₇; and R in photosensitizer PRT4 is isobutyl. According to the absorption spectrum of FIG. 1, it is shown that the value of the light absorption coefficient of photosensitizers of the present invention is better than that of the black dye within a large portion of the wavelength region.

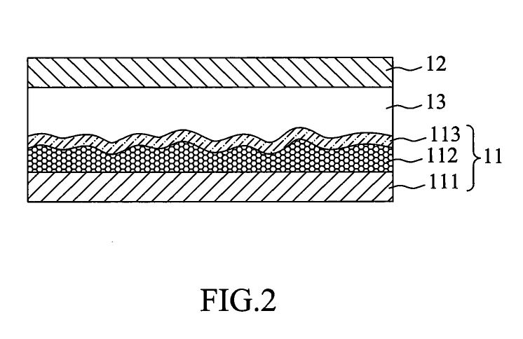

Referring to FIG. 2, a DSSC of an embodiment of the present invention comprises a first electrode 11, a second electrode 12 and an electrolyte 13. The first electrode 11 comprises a transparent conductive substrate 111 and a porous membrane 112. The porous membrane 112, disposed on a surface of the transparent conductive substrate 111, is loaded with the aforementioned photosensitizers 113. The porous membrane 112 comprises a semiconductor material, such as TiO₂. In one embodiment, the transparent conductive substrate 111 comprises F-doped SnO₂ glass (FTO glass). The electrolyte 13 is disposed between the porous membrane 112 and the second electrode 12. The structure of the photosensitizers 113 are identical with the aforementioned photosensitizers, therefore, the detail description is skipped herein.

The aforementioned photosensitizers PRT1˜PRT4 is utilized to produce a DSSC of the present invention. The characteristics are illustrated in table 1, wherein the first electrode 11 comprises photosensitizers PRT1˜PRT4, a porous membrane TiO₂ and FTO glass; the second electrode 12 comprises a Pt electrode, such as a general glass doped with metal Pt and the alloy thereof, chrome (Cr) for example; the electrolyte comprises a mixture consisting of 0.6 M dimethylpropylimidazolium iodide, 0.1 M I₂, 0.1 M LiI, and 0.5 M tert-butylpyridine in acetonitrile.

TABLE 1

| | | short-circuit | | |
|---|---|---|---|---|
| | open-circuit | current | | |
| photosensitizer | voltage (V) | (mAcm⁻²) | fill factor | η (%) |
| PRT1 | 687 | 20.3 | 0.654 | 9.14 |
| PRT2 | 668 | 21.7 | 0.644 | 9.33 |
| PRT3 | 720 | 20.4 | 0.653 | 9.59 |
| PRT4 | 714 | 21.6 | 0.652 | 10.05 |
| Black Dye | 663 | 18.5 | 0.655 | 8.05 |

According to table 1, the photoelectric conversion efficiency η of a DSSC of the present invention is better than that of a dye-sensitized solar cell with black dye. For example, the photoelectric conversion efficiency η of DSSCs comprising PRT1˜PRT4 are 9.14%, 9.33%, 9.59% and 10.05%, respectively. However, the photoelectric conversion efficiency η of a dye-sensitized solar cell employing the black dye is merely 8.05%.

In conclusion, photosensitizers of the present invention are panchromatic photosensitizers and have a better spectrum response in the visible spectral region. A DSSC made of photosensitizers of the present invention has better photoelectric conversion efficiency. In other words, a DSSC of the present invention may comprise a first electrode with thinner porous membrane, which is attributed to the higher absorptivity of these panchromatic photosensitizers, thereby reducing dark current as well as defects during electrode manufacture process so as to increase the open-circuit voltage, and reduce the usage quantities of photosensitizers to lower manufacture cost as well.

While the invention is susceptible to various modifications and alternating descriptions, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A Photosensitizer comprising a chemical formula represented by Formula (a):
ML₁L₂X Formula (a)
wherein M comprises ruthenium atom;
X represents a monodentate anion;
L₁ represents a heterocyclic bidentate ligand, comprising a structural formula represented by Formula (b) or Formula (c) listed below: 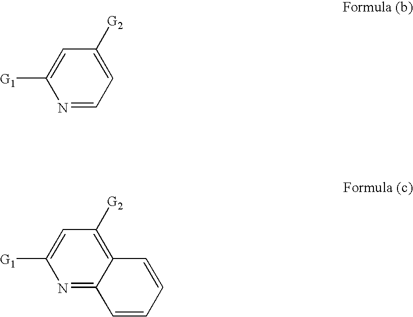
wherein G₁ comprises a structural formula represented by Formula (d), Formula (e), Formula (f) or Formula (g) listed below: 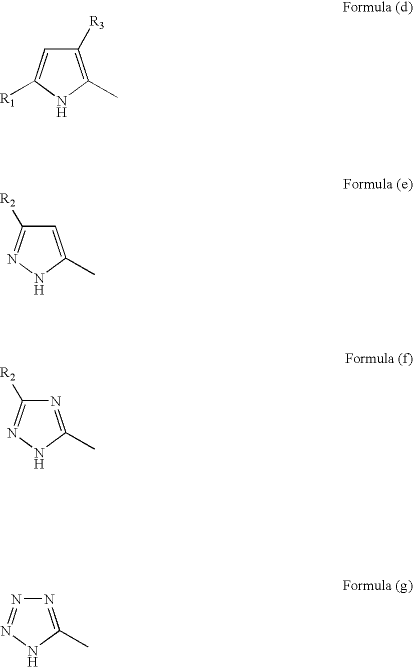
G₂ comprises a structural formula represented by Formula (h), Formula (i) or Formula (j) listed below: 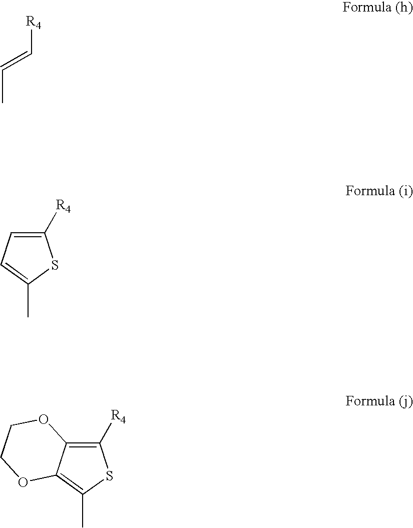
and
L₂ represents a tridentate ligand, comprising a structural formula represented by Formula (k) listed below: 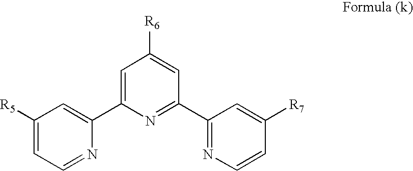
wherein substituents R₁, R₂, R₃, R₄, R₅, R₆ and R₇ of L₁ and L₂ are the same or different, and represent alkyl, alkoxy, alkylthio, alkylamino, halogenated alkyl, phenyl or substituted phenyl group, carboxylic acid or counter anion thereof, sulfonic acid or counter anion thereof, phosphoric acid or counter anion thereof, amino-group, halogens, or hydrogen.

2. Photosensitizers according to claim 1, wherein X comprises halide, pseudohalide, carboxylate, carbanion, sulfate, phosphate or other organic anion.

3. Photosensitizers according to claim 1, wherein X comprises thiocyanate.

4. Photosensitizers according to claim 1, wherein the substituents R₁ and R₃ of L₁ are the same or different, and represent hydrogen, isobutyl or CF₃.

5. Photosensitizers according to claim 1, wherein the substituent R₂ of L₁ comprises hydrogen, isobutyl, CF₃ or a structure formula represented by Formula (l) or Formula (m) listed below:

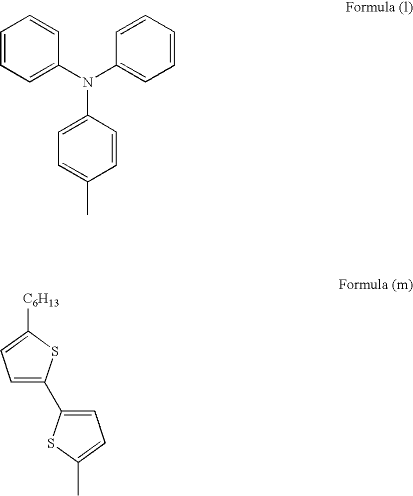

6. Photosensitizers according to claim 1, wherein the substituent R₄ of L₁ comprises an aromatic ring or a functional group of substituted conjugated double bond thereof.

7. Photosensitizers according to claim 1, wherein the substituents R₅, R₆ and R₇ of L₂ are the same or different, and represent hydrogen, carboxylic acid or counter anion thereof, sulfonic acid or counter anion thereof, phosphoric acid or counter anion thereof.

8. A dye-sensitized solar cell comprising:
a first electrode comprising:
a transparent conductive substrate; and
a porous membrane comprising a semiconductor material, disposed on a surface of said transparent conductive substrate, and said porous membrane is loaded with photosensitizers;
a second electrode; and
an electrolyte, disposed between said porous membrane and said second electrode;
wherein said photosensitizers comprising a chemical formula represented by Formula (a):
ML₁L₂X Formula (a)
wherein M comprises ruthenium atom;
X represents a monodentate anion;
L₁ represents a heterocyclic bidentate ligand, comprising a structural formula represented by Formula (b) or Formula (c) listed below: 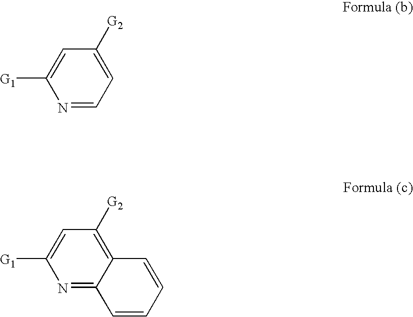
wherein G₁ comprises a structural formula represented by Formula (d), Formula (e), Formula (f) or Formula (g) listed below: 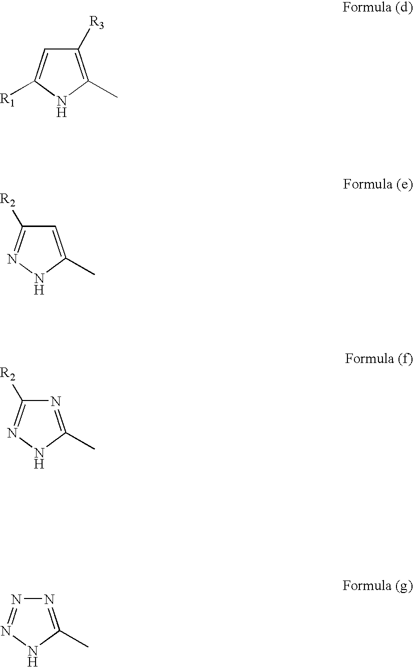
wherein G₂ comprises a structural formula represented by Formula (h), Formula (i) or Formula (j) listed below: 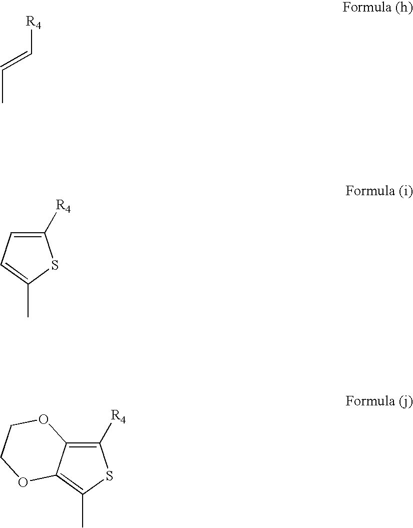
and
L₂ represents a tridentate ligand comprising a structural formula represented by Formula (k) listed below: 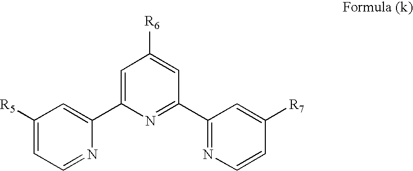
wherein substituents R₁, R₂, R₃, R₄, R₅, R₆ and R₇ of L₁ and L₂ are the same or different, and represent alkyl, alkoxy, alkylthio, alkylamino, halogenated alkyl, phenyl or substituted phenyl group, carboxylic acid or counter anion thereof, sulfonic acid or counter anion thereof, phosphoric acid or counter anion thereof, amino-group, halogens, or hydrogen.

9. A dye-sensitized solar cell according to claim 8, wherein X comprises halide, pseudohalide, carboxylate, carbanion, sulfate, phosphate or other organic anion.

10. A dye-sensitized solar cell according to claim 8, wherein X comprises thiocyanate.

11. A dye-sensitized solar cell according to claim 8, wherein the substituents R₁ and R₃ of L₁ are the same or different, and represent hydrogen, isobutyl or CF₃.

12. A dye-sensitized solar cell according to claim 8, wherein the substituent R₂ of L₁ comprises hydrogen, isobutyl, CF₃ or a structure formula represented by Formula (l) or Formula (m) listed below:

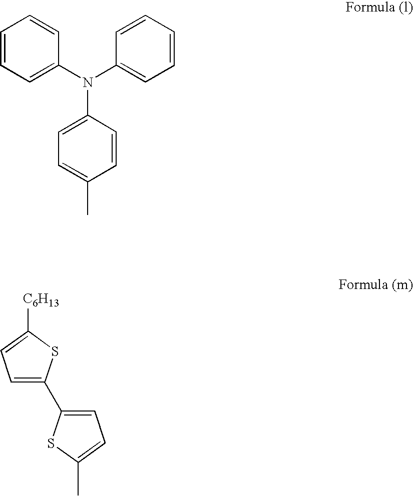

13. A dye-sensitized solar cell according to claim 8, wherein the substituent R₄ of L₁ comprises an aromatic ring or a functional group of substituted conjugated double bond thereof.

14. A dye-sensitized solar cell according to claim 8, wherein the substituents R₅, R₆ and R₇ of L₂ are the same or different, and represent hydrogen, carboxylic acid or counter anion thereof, sulfonic acid or counter anion thereof, phosphoric acid or counter anion thereof.

15. A dye-sensitized solar cell according to claim 8, wherein the material of said semiconductor comprises TiO₂.

16. A dye-sensitized solar cell according to claim 8, wherein said transparent conductive substrate comprises FTO glass.
